(19) United States
(12) Patent Application Publication
(10) Pub. No.: US 2019/0165247 A1
(43) Pub. Date: May 30, 2019

(54) METHOD OF CONTROLLING AMPLITUDE OF MECHANICAL EXCITATION OF A PIEZOELECTRIC POWERED ULTRASONIC STACK INCLUDING UNDER LOAD

(71) Applicant: BRANSON ULTRASONICS CORPORATION, Danbury, CT (US)

(72) Inventor: Scott CALDWELL, New Milford, CT (US)

(73) Assignee: Branson Ultrasonics Corporation, Danbury, CT (US)

(21) Appl. No.: 16/320,920

(22) PCT Filed: Jul. 11, 2018
(86) PCT No.: PCT/US2018/041650

§ 371 Date: Jan. 25, 2019

Related U.S. Application Data
(60) Provisional application No. 62/534,344, filed on Jul. 19, 2017.

(51) Int. Cl. H01L 41/04; B06B 1/06; B29C 65/08; G01H 11/08

(52) U.S. Cl. CPC H01L 41/042; G01H 11/08; B29C 65/08; B06B 1/06

(57) ABSTRACT

An ultrasonic system has a piezoelectric powered ultrasonic stack having a piezoelectric ultrasonic converter excited by an ultrasonic power supply. A control loop feedback controller determines in real time a true amplitude of mechanical excitation at the end of the piezoelectric powered ultrasonic stack including when the piezoelectric powered ultrasonic stack is under load by multiplying one of an amplitude of motional voltage exciting the piezoelectric ultrasonic converter and an amplitude of motional current exciting the piezoelectric ultrasonic converter by a cosine of a phase difference angle between the motional voltage and the motional current and controls the ultrasonic power supply to control an output amplitude of at least one of output voltage and output current of the ultrasonic power supply so that the determined true amplitude of mechanical excitation at the end of the piezoelectric powered ultrasonic stack

### CROSS-REFERENCE TO RELATED APPLICATIONS

This application claims the benefit of U.S. Provisional Application No. 62/534,344, filed on Jul. 19, 2017. The entire disclosure of the above application is incorporated herein by reference.

### FIELD

The present disclosure relates to the control of amplitude of mechanical excitation of piezoelectric powered ultrasonic stacks including under load.

### BACKGROUND

This section provides background information related to the present disclosure which is not necessarily prior art.

A piezoelectric powered ultrasonic stack often used in ultrasonic devices such as ultrasonic welders is an ultrasonic stack where the ultrasonic converter is a piezoelectric converter also commonly referred to as a piezoelectric transducer. An ultrasonic stack includes one or more ultrasonic converters typically attached to one or more acoustically driven passive components. It should however be understood that the ultrasonic stack can have only the ultrasonic converter (or converters) and not acoustically driven passive components. Typically, an ultrasonic stack has an ultrasonic converter attached to a booster and an ultrasonic horn attached to the booster. The booster and ultrasonic horn are acoustically driven passive components. An ultrasonic power supply provides the electrical excitation that drives the ultrasonic converter.

In piezoelectric powered ultrasonic stacks, the RMS amplitude of the motional voltage and the RMS amplitude of the motional current that excite the ultrasonic converter are proportional to the RMS amplitude of the mechanical excitation at the end of the ultrasonic stack in air when the motional voltage and motional current are in phase with each other—that is, when the phase difference between the motional current and the motional current is zero. “RMS” is root mean square. Unless otherwise stated, as used herein the terms motional voltage and motional current mean the motional voltage and motional current that excite the ultrasonic converter, which are each approximate sinusoidal waveforms. The end of the ultrasonic stack is typically the end of the ultrasonic horn such as where an ultrasonic horn tip is typically attached. It should be understood that exciting the ultrasonic transducer is also commonly referred to as driving the ultrasonic transducer. It is thus common practice to control the RMS amplitude of mechanical excitation at the end of the ultrasonic stack by controlling the RMS amplitude of the motional voltage or the RMS amplitude of the motional current.

As long as the control system for the ultrasonic power supply driving the piezoelectric converter maintains a zero phase difference between the motional voltage and the motional voltage, this method for controlling the RMS amplitude of mechanical excitation at the end of the ultrasonic stack is accurate.

However, the RMS amplitude of the motional voltage and the RMS amplitude of the motional current are not proportional to the RMS amplitude of mechanical excitation at the end of the ultrasonic stack when there is phase difference between the motional voltage and the motional current—that is, when there is a non-zero phase difference between the motional voltage and the motional current. Oftentimes, especially when the ultrasonic stack is under load, be it heavy stack loading or load transients, the RMS amplitude of mechanical excitation at the end of the ultrasonic stack is constrained by the loading. In this case, the RMS amplitude of the motional voltage or RMS amplitude of the motional current alone does not represent the RMS amplitude of mechanical excitation at the end of the ultrasonic stack.

As is known in the art, the true or actual RMS amplitude of mechanical excitation at the end of a piezoelectric powered ultrasonic stack is phase dependent and is represented by:

A_{RMS}∝V_{RMS}*cos(φ) (1)

or:

A_{RMS}∝I_{RMS}*cos(φ) (2)

where:
A_{RMS}=RMS amplitude of mechanical excitation at the end of the ultrasonic stack;
V_{RMS}=RMS amplitude of motional voltage;
I_{RMS}=RMS amplitude of motional current;
φ=phase angle between motional voltage and motional current.

FIG. 1 shows a simplified model of an ultrasonic system 101 having a piezoelectric powered ultrasonic stack 100 powered by an ultrasonic power supply 108 and the control of the RMS amplitude of mechanical excitation at the end of ultrasonic stack in the above described manner. Ultrasonic stack 100 includes a piezoelectric converter 102 attached to a booster 104 which in turn is attached to an ultrasonic horn 106. An ultrasonic power supply 108 is electrically coupled to piezoelectric converter 102 and provides the electrical excitation that drives piezoelectric converter 102. Ultrasonic power supply 108 is controlled by an ECU 110, which may be included in ultrasonic power supply 108 or be separate. As used herein, ECU means electronic control unit. ECU 110 includes an RMS converter module 112 and a control loop feedback controller 114 including an error signal module 115 (such as a summer) and control module 116, which are all illustratively implemented in control logic in ECU 110, such as in software. A voltage sensor 118 is coupled to an output 120 of ultrasonic power supply 108 and senses an output voltage of ultrasonic power supply 108 that is provided as an input to RMS converter module 112 of ECU 110. The voltage sensed by voltage sensor 118 is converted to RMS amplitude of the motional voltage by RMS converter module 112 and provided as a feedback input to error signal module 115 of control loop feedback controller 114. Error signal module 115 compares the feedback RMS amplitude of the motional voltage to a desired amplitude setting 122 and generates an error signal that is provided as an input to control module 116. Control module 116 is illustratively a PID controller where PID is proportional-integral-derivative. It should be understood that control module 116 could alternatively be a PI controller where PI is proportional-integral or a P controller where P is proportional. An output of control module 116 is provided as a control input to ultrasonic power supply 108 and controls the amplitude of the output of ultrasonic power supply 108. If ultrasonic power supply 108 is a voltage controlled power supply, control loop feedback controller 114 controls the amplitude of the output voltage of ultrasonic power supply 108 and thus the RMS amplitude of the motional voltage. If ultrasonic power supply 108 is a current controlled power supply, control loop feedback controller 114 controls the amplitude of the output current of the ultrasonic power supply 108 and thus the

RMS amplitude of the motional current.

### SUMMARY

This section provides a general summary of the disclosure, and is not a comprehensive disclosure of its full scope or all of its features.

In accordance with an aspect of the present disclosure, an amplitude of mechanical excitation at an end of a piezoelectric powered ultrasonic stack including when it is under load is controlled to be at a desired amplitude set-point. The piezoelectric powered ultrasonic stack includes a piezoelectric ultrasonic converter that is excited by an ultrasonic power supply. A control loop feedback controller determines in real time a true amplitude of mechanical excitation at the end of the piezoelectric powered ultrasonic stack including when the piezoelectric powered ultrasonic stack is under load by multiplying one of an amplitude of motional voltage exciting the piezoelectric ultrasonic converter and an amplitude of motional current exciting the piezoelectric ultrasonic converter by a cosine of a phase difference angle between the motional voltage and the motional current. The control loop feedback controller controls in real time the ultrasonic power supply to control an output amplitude of at least one of output voltage and output current of the ultrasonic power supply so that the determined true amplitude of mechanical excitation at the end of the piezoelectric powered ultrasonic stack will be at the desired amplitude set-point.

In an aspect, wherein in determining in real time the true amplitude of mechanical excitation at the end of the piezoelectric powered ultrasonic stack, including when the piezoelectric powered ultrasonic stack is under load, the control loop feedback controller multiplies the motional voltage exciting the piezoelectric ultrasonic converter by the cosine of the phase difference angle between the motional voltage and the motional current and controls the output amplitude of the output voltage of the ultrasonic power supply.

In an aspect, the determined true amplitude of mechanical excitation at the end of the piezoelectric powered ultrasonic stack under load is a feedback signal to the control loop feedback controller, the desired amplitude set-point is an input signal to the control loop feedback controller, and the control loop feedback controller generates an error signal indicative of a difference between the feedback signal and the input signal and uses the error signal in controlling the ultrasonic power supply to control the output amplitude of the at least one of output voltage and output current of the ultrasonic power supply.

In an aspect, the control loop feedback controller includes one of a proportional-integral-derivative controller, a proportional-integral controller and a proportional controller. In an aspect, the control loop feedback controller includes the proportional-integral-derivative controller.

In an aspect, the determined true amplitude of mechanical excitation is communicated to a user, such as by display on a display.

In an aspect, the true amplitude is one of a true RMS amplitude, a true peak-to-peak amplitude and a true zero-to-peak amplitude and when the true amplitude is RMS amplitude, one of an RMS amplitude of the motional voltage exciting the piezoelectric ultrasonic converter and an RMS amplitude of motional current exciting the piezoelectric ultrasonic converter is multiplied by the cosine of a phase difference angle between the motional voltage and the motional current to determine true RMS amplitude of mechanical excitation at the end of the piezoelectric powered ultrasonic stack, when the true amplitude is peak-to-peak amplitude, one of peak-to peak amplitude of the motional voltage exciting the piezoelectric ultrasonic converter and peak-to- peak amplitude of motional current exciting the piezoelectric ultrasonic converter is multiplied by the cosine of a phase difference angle between the motional voltage and the motional current to determine true peak-to-peak amplitude of mechanical excitation at the end of the piezoelectric powered ultrasonic stack, and when the true amplitude is zero-peak amplitude, one of zero-to peak amplitude of the motional voltage exciting the piezoelectric ultrasonic converter and zero-to- peak amplitude of motional current exciting the piezoelectric ultrasonic converter is multiplied by the cosine of a phase difference angle between the motional voltage and the motional current to determine true zero-to-peak amplitude of mechanical excitation at the end of the piezoelectric powered ultrasonic stack.

### DRAWINGS

The drawings described herein are for illustrative purposes only of selected embodiments and not all possible implementations, and are not intended to limit the scope of the present disclosure.

FIG. 1 is a diagrammatic view showing a prior art ultrasonic system and prior art control of an ultrasonic power supply that excites a piezoelectric powered ultrasonic stack of the ultrasonic system; and

FIG. 2 is diagrammatic view showing control in accordance with an aspect of the present disclosure of the piezoelectric powered ultrasonic stack of the ultrasonic system of FIG. 1.

Corresponding reference numerals indicate corresponding parts throughout the several views of the drawings.

### DETAILED DESCRIPTION

Example embodiments will now be described more fully with reference to the accompanying drawings.

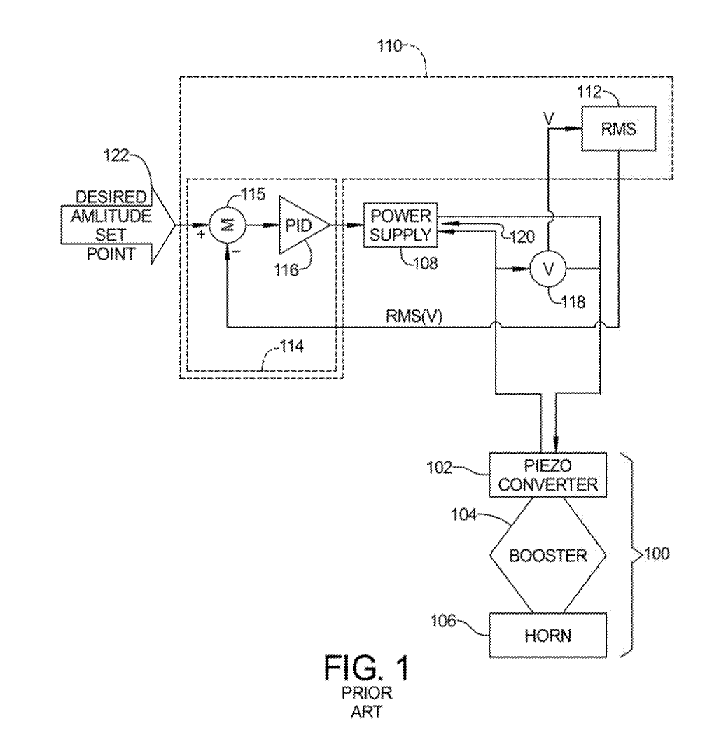

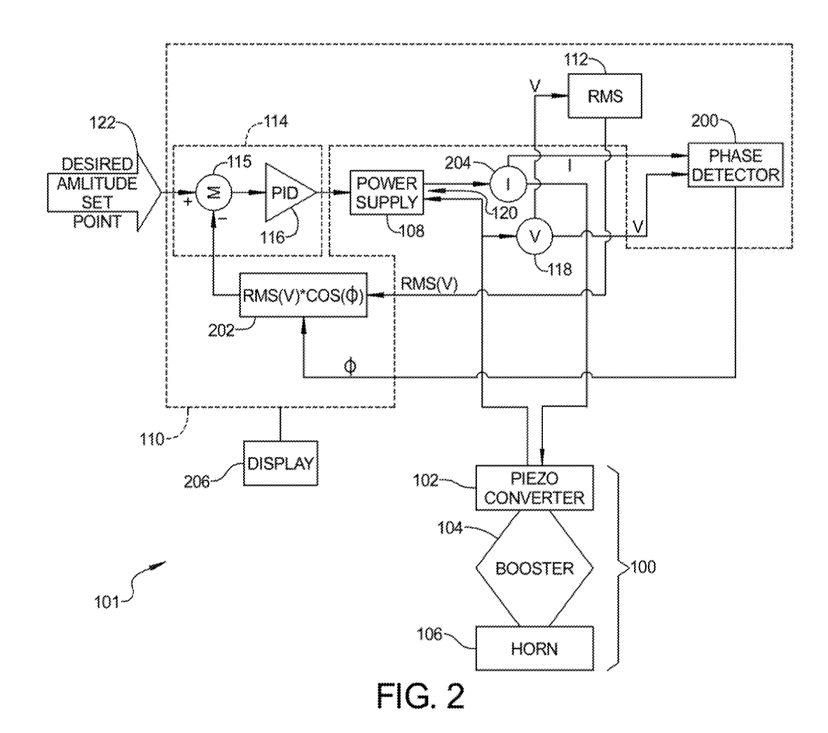

FIG. 2 is a simplified model showing ultrasonic system 101 and its control in accordance with an aspect of the present disclosure of ultrasonic power supply 108 that excites piezoelectric powered ultrasonic stack 100. It should be understood that ultrasonic system 101, piezoelectric powered ultrasonic stack 100 and ultrasonic power supply 108 are the same as shown in FIG. 1, but with the control of ultrasonic power supply 108 being different.

In addition to RMS converter module 112, control loop feedback controller 114, ECU 110 includes phase detector module 200 and feedback signal module, illustratively implemented in control logic of ECU 110, such as in software. It should be understood that RMS converter module 112, control loop feedback controller 114 and phase detector module 200 could be separate modules. In addition to voltage sensor 110 coupled to output 120 of ultrasonic power supply 108, a current sensor 204 is also coupled to output 120 of ultrasonic power supply 108 senses an output current of ultrasonic power supply 108. Phase detector module 200 detects a phase difference angle between the output voltage and the output current of ultrasonic power supply 108 and this phase difference angle is an input to feedback signal module 202 of ECU 110.

The RMS amplitude of the motional voltage from RMS converter module 112 is also an input to feedback signal module 202. Feedback signal module 202 generates a feedback signal that is the RMS amplitude of the motional voltage times the cosine of the angle of the phase difference between the motional voltage output of ultrasonic power supply 108 and the motional current of ultrasonic power supply 108. This feedback signal is referred to herein as true amplitude of mechanical excitation feedback signal and is directly indicative of the true amplitude of mechanical excitation at the end of ultrasonic stack 100 including when ultrasonic stack 100 is under load and there is a phase difference angle between the motional voltage and the motional current. In the example shown in FIG. 2, the true amplitude of mechanical excitation signal is directly indicative of the true RMS amplitude of mechanical excitation at the end of ultrasonic stack 100 including when ultrasonic stack 100 is under load and there is a phase difference angle between the motional voltage and the motional current.

It should be understood that control loop feedback controller 114 controls in real time the output of ultrasonic power supply 108. In doing so, control loop feedback controller 114 in real time monitors the output voltage of ultrasonic power supply 108, converts this output voltage to the RMS amplitude of the motional voltage output of ultrasonic power supply 108, detects the phase difference angle between the motional voltage output and motional current output of ultrasonic power supply 108, generates the true RMS amplitude of mechanical excitation feedback signal, and controls the output of ultrasonic power supply 108 accordingly so that the RMS amplitude of mechanical excitation at the end of ultrasonic stack 100 will be at the desired amplitude set point from amplitude set point 122.

In an aspect, the determined true RMS amplitude of mechanical excitation feedback at the end of ultrasonic stack 100 is communicated such as to a user by display on a display 206 by control loop feedback controller 114.

It should be understood that zero to peak amplitude, or peak to peak amplitude can be substituted for RMS amplitude in all references to RMS amplitude in these formulas, references and diagrams and be equally valid.

As used herein, the term controller, control module, control system, or the like may refer to, be part of, or include an Application Specific Integrated Circuit (ASIC); an electronic circuit; a combinational logic circuit; a field programmable gate array (FPGA); a processor (shared, dedicated, or group) that executes code; a programmable logic controller, programmable control system such as a processor based control system including a computer based control system, a process controller such as a PID controller, or other suitable hardware components that provide the described functionality or provide the above functionality when programmed with software as described herein; or a combination of some or all of the above, such as in a system-on-chip. The term module may include memory (shared, dedicated, or group) that stores code executed by the processor. When it is stated that such a device performs a function, it should be understood that the device is configured to perform the function by appropriate logic, such as software, hardware, or a combination thereof.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A method of controlling amplitude of mechanical excitation at an end of a piezoelectric powered ultrasonic stack including when it is under load to be at a desired amplitude set-point wherein a piezoelectric ultrasonic converter of the ultrasonic stack is excited by an ultrasonic power supply, comprising:
determining in real time with a control loop feedback controller a true amplitude of mechanical excitation at the end of the piezoelectric powered ultrasonic stack including when the piezoelectric powered ultrasonic stack is under load by multiplying one of an amplitude of motional voltage exciting the piezoelectric ultrasonic converter and an amplitude of motional current exciting the piezoelectric ultrasonic converter by a cosine of a phase difference angle between the motional voltage and the motional current; and
controlling in real time the ultrasonic power supply with the control loop feedback controller to control an output amplitude of at least one of output voltage and output current of the ultrasonic power supply so that the determined true amplitude of mechanical excitation at the end of the piezoelectric powered ultrasonic stack will be at the desired amplitude set-point.

2. The method of claim 1 wherein determining in real time with the control loop feedback controller the true amplitude of mechanical excitation at the end of the piezoelectric powered ultrasonic stack includes multiplying the amplitude of motional voltage exciting the piezoelectric ultrasonic converter by the cosine of the phase difference angle between the motional voltage and the motional current and controlling in real time the ultrasonic power supply with the control loop feedback controller to control the output amplitude of the output voltage.

3. The method of claim 1 including using the determined true amplitude of mechanical excitation at the end of the piezoelectric powered ultrasonic stack as a feedback signal to the control loop feedback controller and using the desired amplitude set-point as an input signal to the control loop feedback controller and having the control loop feedback controller generate an error signal indicative of a difference between the feedback signal and the input signal and use the error signal in controlling the ultrasonic power supply to control the output amplitude of the at least one of output voltage and output current of the ultrasonic power supply.

4. The method of claim 3 including using as the control loop feedback controller one of a proportional-integral-derivative controller, a proportional-integral controller and a proportional controller.

5. The method of claim 4 including using as the control loop feedback controller the proportional-integral-derivative controller.

6. The method of claim 1 including displaying on a display the determined true amplitude of mechanical excitation.

7. The method of claim 1 wherein determining in real time with a control loop feedback controller a true amplitude of mechanical excitation at the end of the piezoelectric powered ultrasonic stack includes determining the true amplitude as one of a true RMS amplitude, a true zero-to-peak amplitude and a true peak-to-peak amplitude and
when the true amplitude is RMS amplitude, one of an RMS amplitude of the motional voltage exciting the piezoelectric ultrasonic converter and an RMS amplitude of motional current exciting the piezoelectric ultrasonic converter is multiplied by the cosine of a phase difference angle between the motional voltage and the motional current to determine true RMS amplitude of mechanical excitation at the end of the piezoelectric powered ultrasonic stack,
when the true amplitude is peak-to-peak amplitude, one of peak-to peak amplitude of the motional voltage exciting the piezoelectric ultrasonic converter and peak-to- peak amplitude of motional current exciting the piezoelectric ultrasonic converter is multiplied by the cosine of a phase difference angle between the motional voltage and the motional current to determine true peak-to-peak amplitude of mechanical excitation at the end of the piezoelectric powered ultrasonic stack, and
when the true amplitude is zero-peak amplitude, one of zero-to peak amplitude of the motional voltage exciting the piezoelectric ultrasonic converter and zero-to-peak amplitude of motional current exciting the piezoelectric ultrasonic converter is multiplied by the cosine of a phase difference angle between the motional voltage and the motional current to determine true zero-to-peak amplitude of mechanical excitation at the end of the piezoelectric powered ultrasonic stack.

8. An ultrasonic system, comprising:
a piezoelectric powered ultrasonic stack having a piezoelectric ultrasonic converter excited by an ultrasonic power supply;
a control loop feedback controller, the control loop feedback controller configured to determine in real time a true amplitude of mechanical excitation at the end of the piezoelectric powered ultrasonic stack including when the piezoelectric powered ultrasonic stack is under load by multiplying one of an amplitude of motional voltage exciting the piezoelectric ultrasonic converter and an amplitude of motional current exciting the piezoelectric ultrasonic converter by a cosine of a phase difference angle between the motional voltage and the motional current; and
the control loop feedback controller configured to control in real time the ultrasonic power supply to control an output amplitude of at least one of output voltage and output current of the ultrasonic power supply so that the determined true amplitude of mechanical excitation at the end of the piezoelectric powered ultrasonic stack will be at a desired amplitude set-point.

9. The ultrasonic system of claim 8 wherein in determining in real time the true amplitude of mechanical excitation at the end of the piezoelectric powered ultrasonic stack the control loop feedback controller is configured to multiply the amplitude of motional voltage exciting the piezoelectric ultrasonic converter by the cosine of a phase difference angle between the motional voltage and the motional current and the control loop feedback controller is configured to control in real time the ultrasonic power supply to control the output amplitude of the output voltage of the ultrasonic power supply.

10. The ultrasonic system of claim 8 wherein the determined true amplitude of mechanical excitation at the end of the piezoelectric powered ultrasonic stack is a feedback signal to the control loop feedback controller, the desired amplitude set-point is an input signal to the control loop feedback controller, and the control loop feedback controller is configured to generate an error signal indicative of a difference between the feedback signal and the input signal and use the error signal in controlling the ultrasonic power supply to control the output amplitude of the at least one of output voltage and output current of the ultrasonic power supply.

11. The ultrasonic system of 10 wherein the control loop feedback controller includes one of a proportional-integral-derivative controller, a proportional-integral controller and a proportional controller.

12. The ultrasonic system of 11 wherein the control loop feedback controller includes the proportional-integral-derivative controller.

13. The ultrasonic system of claim 8 including a display on which the determined true amplitude of mechanical excitation at the end of the ultrasonic stack is displayed.

14. The ultrasonic system of claim 8 wherein the true amplitude of mechanical excitation at the end of the ultrasonic stack is any of RMS amplitude, peak-to-peak amplitude and zero-to-peak amplitude and
when the true amplitude is RMS amplitude, one of an RMS amplitude of the motional voltage exciting the piezoelectric ultrasonic converter and an RMS amplitude of motional current exciting the piezoelectric ultrasonic converter is multiplied by the cosine of a phase difference angle between the motional voltage and the motional current to determine true RMS amplitude of mechanical excitation at the end of the piezoelectric powered ultrasonic stack,
when the true amplitude is peak-to-peak amplitude, one of peak-to peak amplitude of the motional voltage exciting the piezoelectric ultrasonic converter and peak-to- peak amplitude of motional current exciting the piezoelectric ultrasonic converter is multiplied by the cosine of a phase difference angle between the motional voltage and the motional current to determine true peak-to-peak amplitude of mechanical excitation at the end of the piezoelectric powered ultrasonic stack, and
when the true amplitude is zero-peak amplitude, one of zero-to peak amplitude of the motional voltage exciting the piezoelectric ultrasonic converter and zero-to- peak amplitude of motional current exciting the piezoelectric ultrasonic converter is multiplied by the cosine of a phase difference angle between the motional voltage and the motional current to determine true zero-to-peak amplitude of mechanical excitation at the end of the piezoelectric powered ultrasonic stack.
